(19) United States
(12) Patent Application Publication
(10) Pub. No.: US 2026/0020235 A1
(43) Pub. Date: Jan. 15, 2026

(54) METHOD FOR MANUFACTURING VERTICAL GATES OF TRANSISTORS AND CORRESPONDING INTEGRATED CIRCUIT

(71) Applicant: STMicroelectronics International N.V., Geneva (CH)

(72) Inventors: Christian RIVERO, Peynier (FR); Julien DELALLEAU, Rousset (FR)

(73) Assignee: STMicroelectronics International N.V., Geneva (CH)

(21) Appl. No.: 19/261,524

(22) Filed: Jul. 7, 2025

(30) Foreign Application Priority Data
Jul. 9, 2024 (FR) FR2407484

(51) Int. Cl. H10B 41/35

(52) U.S. Cl. CPC H10B 41/35

(57) ABSTRACT

An integrated circuit includes a semiconductor substrate having a front face and vertical gates of transistors in the semiconductor substrate. To make the vertical gates, gate trenches are formed in the substrate extending in a first direction of the front face. Subsequently, shallow insulation trenches are formed extending in a second direction of the front face perpendicular to the first direction and delimiting therebetween active regions and the vertical gates.

### PRIORITY CLAIM

This application claims the priority benefit of French Application for Patent No. FR2407484, filed on Jul. 9, 2024, the content of which is hereby incorporated by reference in its entirety to the maximum extent allowable by law.

### TECHNICAL FIELD

Implementations and embodiments relate to integrated circuits and, in particular, to the manufacture of transistors with vertical gates.

### BACKGROUND

FIG. 1 illustrates a conventional example of forming transistors with vertical gates in a semiconductor substrate SUB, in a perspective view oriented by an orthogonal reference frame XYZ, and in a top view located in a plane XY.

The gate regions TRG are formed in trenches sinking vertically in the direction Z into the semiconductor substrate SUB, and extending continuously in a first direction X crossing active regions ACT of the substrate extending in a second direction Y and delimited by shallow insulation regions STI.

Conduction regions of the transistors are typically formed in the active region on either side of the vertical gate TRG.

This conventional formation type has the drawback of an “irreducible” pitch PTx in the first direction X between two transistors with vertical gates. Indeed, a reduction of the distance in the direction X between two neighboring active regions ACT, increases the risk and the amount of current leakage (commonly referred to in the art as “reachthrough”) originating from the conduction regions of the neighboring transistors. The leakage transits via a conduction channel formed along the trench containing the gate regions in the substrate SUB, below the depth of the shallow insulation regions STI. Indeed, because of the greater dynamics of etching of the trenches in the dielectric material of the regions STI than in the semiconductor material of the substrate SUB, there is conventionally a region able to form a conduction channel at the interface of the vertical gate trenches with the substrate below the shallow insulation trenches STI, even though the depth of the vertical gates in the substrate SUB and the active regions ACT is also smaller than the depth of the shallow insulation regions STI.

FIG. 2 illustrates another conventional example of formation of transistors with vertical gates in a semiconductor substrate SUB, in a perspective view directed by an orthogonal reference frame XYZ, and in a top view located in a plane XY.

The gate regions TRG are individually formed in local trenches, in other words in wells, sinking vertically in the direction Z into the semiconductor substrate SUB. Each formation of a trench or well is drawn so as to form one single transistor vertical gate.

Conduction regions of the transistor are typically formed in the active regions on either side, in the second direction Y, of the vertical gate TRG.

This conventional formation type also has the drawback of an “irreducible” pitch PTx in the first direction X between two transistors with vertical gates. Indeed, rules of drawing individual vertical gates impose a minimum spacing Amin, in the first direction X, between the etchings of the individual “wells” containing the gates. Thus, a reduction of the distance in the direction X between two neighboring active regions ACT is limited by the accuracy of the methods for etching this type of trenches or wells.

However, there is a constant need for reducing the dimensions of semiconductor devices and integrated circuits, commonly expressed according to Moore's law principle.

There is a need in the art for implementations and embodiments providing solutions to the aforementioned difficulties, allowing reducing the pitch PTx in the first direction X between two transistors with vertical gates.

### SUMMARY

In an embodiment, a method is provided for manufacturing an integrated circuit, comprising forming vertical gates of transistors, comprising, in a semiconductor substrate having a front face, forming gate trenches extending in a first direction of the front face, and, subsequently, forming shallow insulation trenches extending in a second direction of the front face perpendicular to the first direction, delimiting therebetween active regions and the vertical gates.

Thus, because forming the shallow insulation trenches is done after forming the gate trenches, the delimitation of the active regions in the semiconductor substrate also delimits the vertical gates in the gate trenches. In other words, the vertical gates are thus individualized along the first direction, starting from each continuous gate trench in the first direction, in a so-called “self-aligned” manner with delimitation of the active regions by formation of the shallow insulation regions.

Indeed, the expression “self-aligned” means, as is common in the field of semiconductor device manufacturing, that the aligned position of two entities results from a common formation step, and, in particular, does not result from positioning a second formation aligned on an element that is already formed.

According to one implementation, forming the gate trenches comprises etching first trenches sinking vertically into the substrate from the front face and extending longitudinally in the first direction, the sidewalls of the first trenches having an inclination directed so that the width of the first trenches, in the second direction, is larger at the front face than at the bottom of the first trenches.

For example, in a conventional manner, forming the gate trenches may further comprise forming a dielectric layer such as silicon dioxide, over the bottom and the sidewalls of the first trenches, and filling the first trenches with a conductive material such as polycrystalline silicon.

According to one implementation forming the shallow insulation trenches comprises etching second trenches sinking vertically into the substrate from the front face and extending longitudinally in the second direction, the sidewalls of the second trenches having an inclination directed so that the width of the active regions and the vertical gates delimited therebetween, in the first direction, is larger at the bottom of the first trenches than at the front face.

For example, in a conventional manner, forming the shallow insulation trenches may further comprise filling the second trench with a dielectric material, typically silicon dioxide.

According to one implementation, the method comprises forming metallic contacts connecting the vertical gates aligned in the first direction to a metallic track in at least one first metal level.

According to one implementation, forming the gate trenches comprises at least one amongst: forming first gate trenches having a first depth smaller than the depth of the shallow insulation regions, and forming second gate trenches having a second depth larger than the depth of the shallow insulation regions.

According to one implementation, the method comprises beforehand forming, in the semiconductor substrate, a series of P-type wells and N-type wells alternately in the first direction, positioned opposite the locations of the future active regions.

According to another aspect, an integrated circuit is also provided, including transistors with a vertical gate in a semiconductor substrate having a front face, the vertical gates being laterally delimited by shallow insulation trenches located on either side of the vertical gates in a first direction of the plane of the front face, and by active regions of the semiconductor substrate located on either side of the vertical gates in a second direction of the plane of the front face perpendicular to the first direction; the width of the vertical gates in the first direction being strictly equal to the width of the active regions in the first direction.

The equality between the width of the vertical gates and the width of the active regions in the first direction is a direct consequence of the delimitation of the vertical gates self-aligned with the delimitation of the active regions, both made between the lateral insulation regions.

According to one embodiment, the sidewalls of the vertical gates, located on either side of the vertical gates in the first direction, having an inclination directed so that the width of the vertical gates in the first direction is larger at the bottom of the vertical gates than at the front face of the substrate.

For example, in a conventional manner, the vertical gates may further comprise a conductive material volume such as polycrystalline silicon, wrapped by a dielectric layer such as silicon dioxide, over the bottom and the lateral sidewalls on either side of the vertical gates in the second direction.

For example, in a conventional manner, the shallow insulation trenches may further comprise a filling of second trenches with a dielectric material, typically made of silicon dioxide.

According to one embodiment, the sidewalls of the vertical gates, located on either side of the vertical gates in the second direction, have an inclination directed so that the width of the vertical gates in the second direction is larger at the front face of the substrate than at the bottom of the vertical gates.

According to one embodiment, the integrated circuit further comprises metallic contacts connecting the vertical gates aligned in the first direction to a metallic track located in at least one first metal level.

According to one embodiment, the transistors with vertical gates include at least one amongst: a group of transistors including first vertical gates having a first depth smaller than the depth of the shallow insulation regions, and a group of transistors including second vertical gates having a second depth larger than the depth of the shallow insulation regions.

According to one embodiment, the active regions include a series of P-type wells and of N-type wells alternately in the first direction.

### BRIEF DESCRIPTION OF THE DRAWINGS

Other advantages and features of the invention will appear upon examining the detailed description of non-limiting implementations and embodiments, and from the appended drawings, wherein the figures:

FIG. 1 illustrates a conventional example of formation of transistors with vertical gates in a semiconductor substrate;

FIG. 2 illustrates another conventional example of formation of transistors with vertical gates in a semiconductor substrate;

FIGS. 3A to 3C, 4A to 4C, 5A to 5C, 6A to 6C, and 7A to 7C illustrate corresponding steps of a method for manufacturing an integrated circuit;

FIGS. 8A, 8B and 8C illustrating an example of application in a complementary “CMOS” type logic circuit; and

FIGS. 9A-9B, 10A-10B and 11A-11C illustrate corresponding steps in a method for manufacturing vertical gates and active regions of transistors.

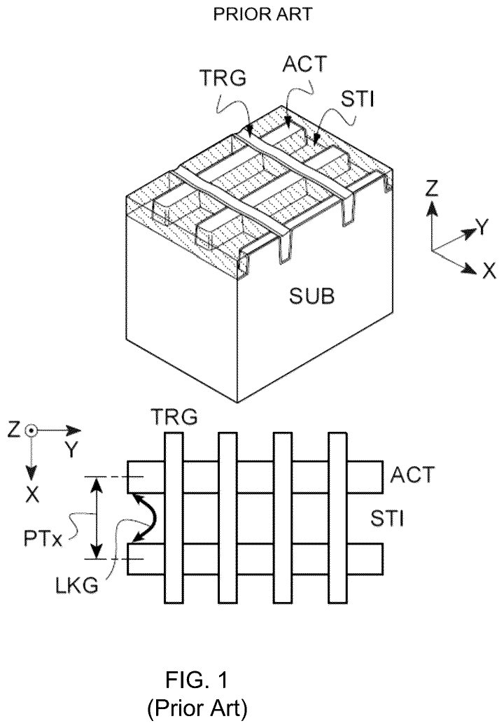

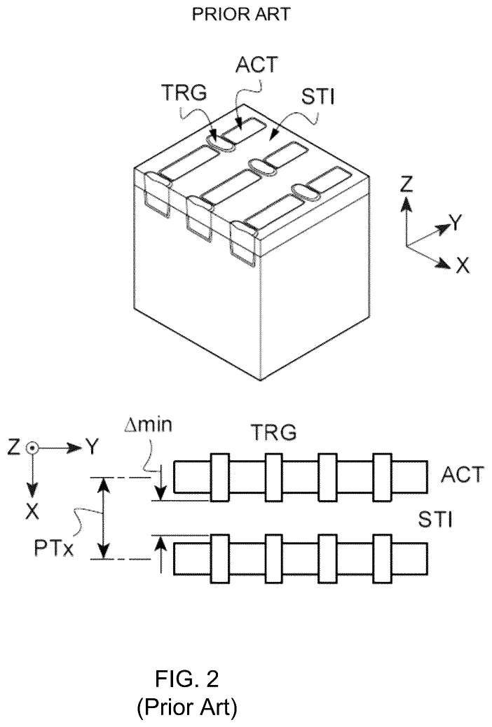

### DETAILED DESCRIPTION

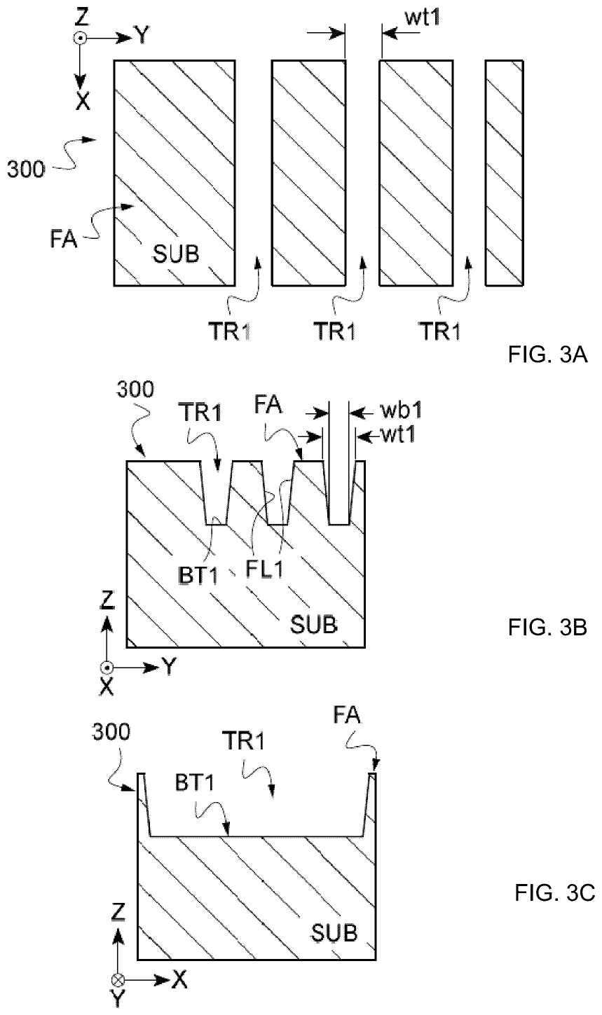

FIGS. 3A to 3C, 4A to 4C, 5A to 5C, 6A to 6C, and 7A to 7C illustrate steps 300, 400, 500, 600, 700 of a method for manufacturing an integrated circuit, in particular for forming vertical gates TRG and active regions ACT of transistors in a semiconductor substrate SUB, in a first case where the vertical gates VG have a first depth smaller than the depth of shallow insulation regions STI.

In a common orthogonal reference frame XYZ, the direction X is so-called the first direction, the direction Y is so-called the second direction, the direction Z is so-called the vertical direction.

The face of the semiconductor substrate SUB on which the manufacturing steps are done is so-called the front face FA, and is located in a plane XY, perpendicular to the vertical direction Z.

FIG. 3A illustrates step 300 in a top view of the substrate SUB, in the plane XY of the front face FA.

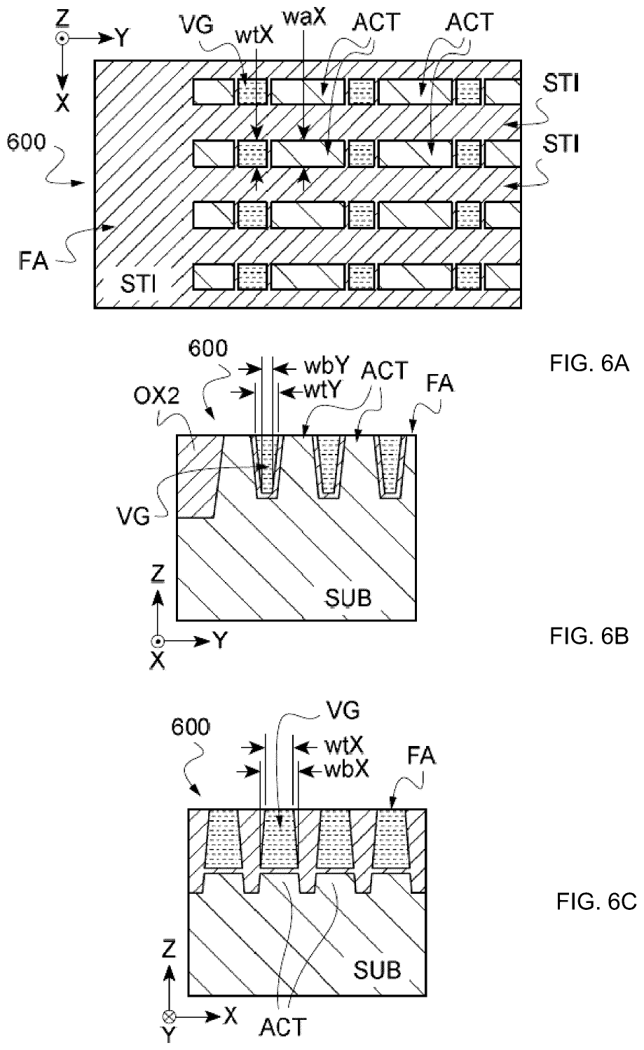

FIG. 3B illustrates step 300 in a sectional view in a plane YZ positioned at a location containing the future active regions ACT (FIG. 6B).

FIG. 3C illustrates step 300 in a sectional view, in the plane XZ, of the semiconductor substrate SUB.

Step 300 relates to forming, in the semiconductor substrate SUB, gate trenches TRG extending in the first direction X.

Thus, forming the gate trenches TRG comprises, in step 300, etching first trenches TR1 which sink vertically in the direction Z into the substrate SUB from the front face FA and extend longitudinally in the first direction X.

Laterally, in the second direction Y, the width wt1 of the first trenches TR1 at the front face FA is larger than the width wb1 of the first trenches TR1 at the bottom BT1.

Indeed, the etching creates sidewalls FL1 of the first trenches TR1 having an inclination directed in the direction forming an outward opening of the bottom BT1. The inclination may measure a few degrees, for example less than 10 degrees, typically between 1 and 6 degrees, with respect to the vertical Z, symmetrically on each sidewall FL1.

For example, the technique for etching 300 the first trenches TR1 may be of the ion bombardment type, commonly so-called “dry etching”, such as reactive ion etchings (“RIE”). In particular, the etching 300 may provide for a photosensitive resin mask (not shown) to develop the etching pattern as well as a hard mask (not shown), typically including a superposition of dielectric layers such as silicon oxide and silicon nitride.

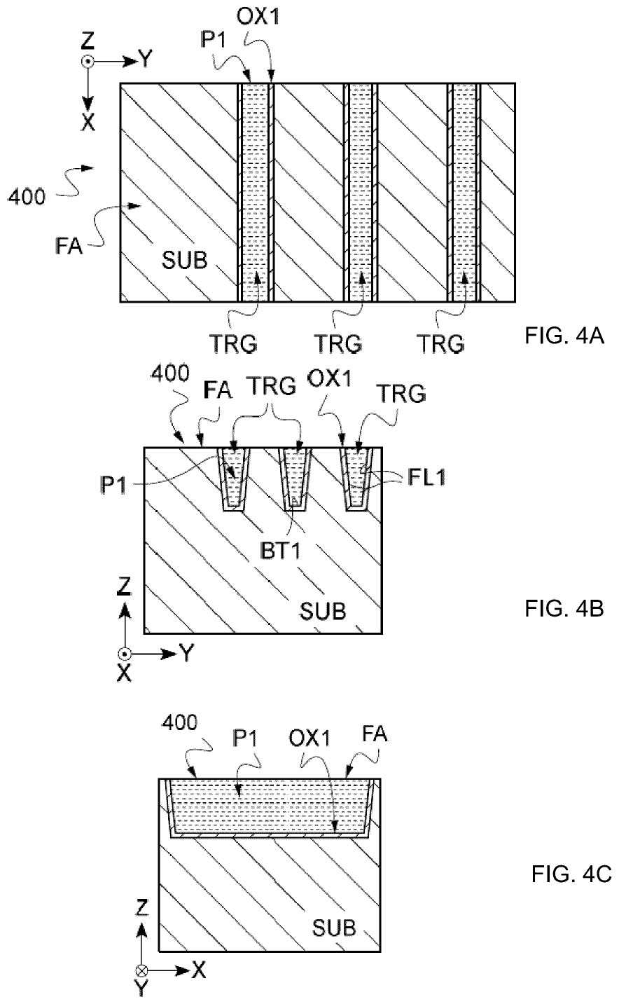

FIG. 4A illustrates step 400 in the plane XY of FIG. 3A.

FIG. 4B illustrates step 400 in the plane YZ of FIG. 3B.

FIG. 4C illustrates step 400 in the plane XZ of FIG. 3C.

Step 400 completes forming, in the semiconductor substrate SUB, of the gate trenches TRG extending in the first direction X.

Forming the gate trenches TRG may further comprise in step 400 forming a dielectric layer OX1, of the gate dielectric type, commonly made of silicon dioxide, over the bottom BT1 and the sidewalls FL1 of the first trenches TR1, and filling the first trenches with a gate conductive material P1, typically such as polycrystalline silicon.

For example, filling with the conductive material P1 comprises a deposition filling the trenches with excess up to the top of the front face FA. For example, the deposition techniques may be a chemical vapor deposition (CVD) type or physical vapor deposition (PVD) type.

Afterwards, a chemical mechanical polishing (commonly “Chemical-Mechanical Planarization” (CMP)) allows removing the excess material, using for example a layer of the hard mask as a stop layer.

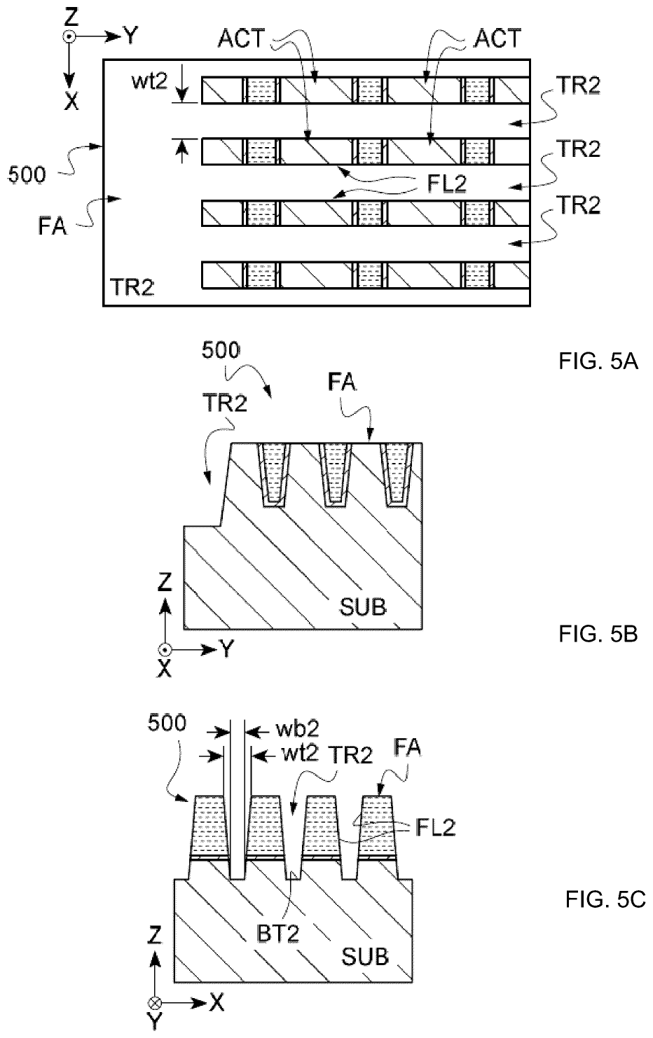

FIG. 5A illustrates step 500 in the plane XY of FIGS. 3A and 4A.

FIG. 5B illustrates step 500 in the plane YZ of FIGS. 3B and 4B.

FIG. 5C illustrates step 500 in the plane XZ of FIGS. 3C and 4C.

Step 500 relates to forming, in the semiconductor substrate SUB, shallow insulation trenches STI extending in the second direction Y, after forming the gate trenches TRG.

In particular, the shallow insulation trenches STI allow delimiting therebetween active regions ACT of the semiconductor substrate SUB.

Thus, forming the shallow insulation trenches STI comprises in step 500 etching second trenches TR2 which sink vertically in the direction Z into the substrate SUB starting from the front face FA and extend longitudinally in the second direction Y.

Thus, the second trenches TR2 are also etched through the gate trenches TRG formed in the previously-described steps 300, 400. The etching dynamics in the structures of the gate trenches TRG are substantially the same as in the substrate SUB.

Laterally, in the first direction X, the width wt2 of the second trenches TR2 at the front face FA is larger than the width wb2 of the second trenches TR2 at the bottom BT1.

Indeed, the etching creates sidewalls FL2 of the second trenches TR2 having an inclination directed in the direction forming an outward opening of the bottom BT2. The inclination may measure a few degrees, for example from 1 to 10 degrees, with respect to the vertical Z, symmetrical on each sidewall FL2.

For example, the technique of etching 500 the second trenches TR2 may be substantially of the same type, typically “RIE”, as the etching 300 of the first trenches TR1, and using in particular a second hard mask (not shown).

FIG. 6A illustrates step 600 in the plane XY of FIGS. 3A, 4A and 5A.

FIG. 6B illustrates step 600 in the plane YZ of FIGS. 3B, 4B and 5B.

FIG. 6C illustrates step 600 in the plane XZ of FIGS. 3C, 4C and 5C.

Step 600 completes the formation, in the semiconductor substrate SUB, of the shallow insulation trenches STI extending in the second direction Y.

The formation of the shallow insulation trenches STI comprises in step 600 filling the second trenches TR2 with a dielectric material OX2, typically made of silicon dioxide.

For example, filling with the dielectric material OX2 comprises a thermal oxidation of the sidewalls FL2 and of the bottom BT2 of the second trenches TR2, followed by excess filling of the trenches TR2, up to the top of the front face FA. For example, the deposition techniques may be a chemical vapor deposition (CVD) type or physical vapor deposition (PVD) type.

Afterwards, a chemical-mechanical planarization “CMP” allows removing the excess dielectric material, using for example a hard-mask layer that has been used in the second etching (not shown) as a stop layer.

To summarize, forming of gate trenches TRG extending in the first direction X of the front face FA in steps 300, 400, and subsequently in steps 500, 600, forming of shallow insulation trenches STI extending in the second direction Y of the front face FA, perpendicular to the first direction X, have been described with reference to FIGS. 3A to 3C, 4A to 4C, 5A to 5C, and 6A to 6D.

Thus, since forming of the shallow insulation trenches STI is done after forming of the gate trenches TRG, the shallow insulation trenches STI delimit therebetween the active regions ACT of the semiconductor substrate SUB, and also delimit therebetween the gate trenches TRG in the first direction X.

In other words, vertical gates VG are thus individualized along the first direction X, starting from the gate trenches TRG continuous in the first direction X, in a so-called “self-aligned” manner with delimitation of the active regions ACT.

In particular, it should be noted that it results from this self-alignment that the width wtX, wbX of the vertical gates VG in the first direction X is strictly equal to the width wax of the active regions ACT in the first direction X, at any identical depth Z between the front face FA and the bottom (BT1) of the vertical gate VG.

Besides, since the sidewalls FL2 of the second trenches TR2 have an inclination forming an outward opening of the bottom BT2, i.e. since the width wt2 of the second trenches TR2 at the front face FA is larger than the width wb2 of the second trenches TR2 at the bottom BT1; then the sidewalls of the portions delimited between two shallow insulation trenches STI (i.e. the sidewalls of the vertical gates VG and of the active regions ACT) have the reverse inclination, closing into a bottleneck from the bottom BT2 outwards.

Thus, in other words, the width wbX in the first direction X of the vertical gates VG at the bottom BT1 of the first trench TR1 is larger than the width wtX in the first direction X of the vertical gates VG at the front face FA.

However, the sidewalls of the vertical gates VG, located on either side of the vertical gates in the second direction Y, have an inclination directed so that the width wtY of the vertical gates VG in the second direction Y at a front face FA of the substrate is larger than the width wbY of the vertical gates in the second direction Y at the bottom BT1 of the first trench TR1.

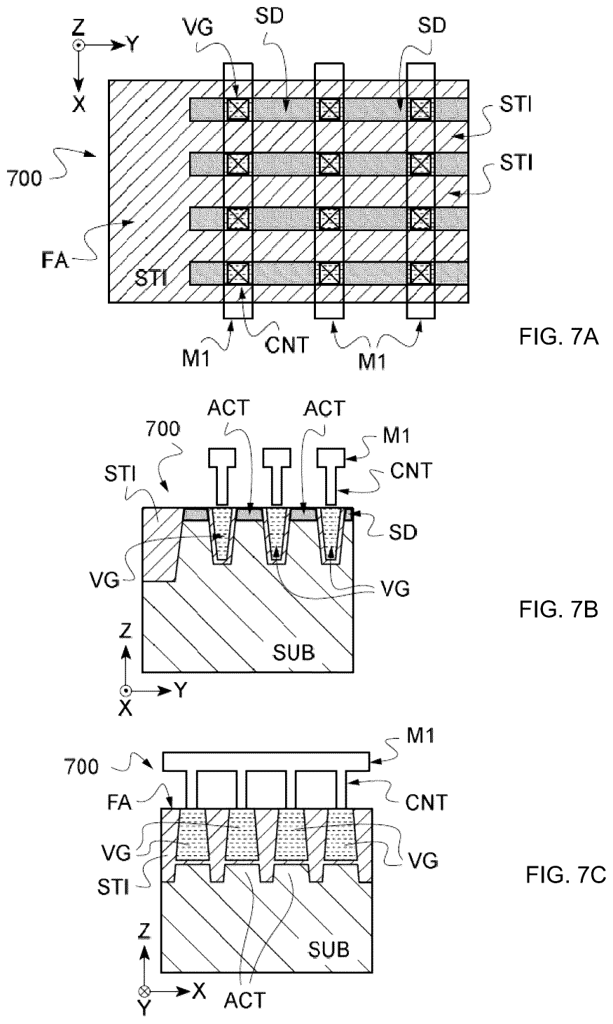

FIG. 7A illustrates step 700 in the plane XY of FIGS. 3A, 4A, 5A and 6A.

FIG. 7B illustrates step 700 in the plane YZ of FIGS. 3B, 4B, 5B and 6B.

FIG. 7C illustrates step 700 in the plane XZ of FIGS. 3C, 4C, 5C and 6C.

Step 700 substantially corresponds to a completion of the semiconductor portion of the integrated circuit (commonly so-called “Front End Of Line” (FEOL) manufacturing processing), in particular until the beginning of the phase of forming the interconnection portion (commonly so-called “Back End Of Line” (BEOL) manufacturing processing).

In step 700, conduction regions SD of the transistors with vertical gates have been formed in particular, typically N (or P) type doped regions in the P (or N) type active regions ACT located on either side of the respective vertical gates VG (in the second direction Y). In practice, the P (or N) type active regions ACT are located between the adjacent vertical gates, since the adjacent transistors will typically have common drains and sources.

Thus, a channel region may be formed from one conduction region SD to the other, in the active region ACT located along a sidewall, the bottom and the other sidewall of the vertical gate VG.

Furthermore, step 700 advantageously comprises forming metallic contacts CNT connecting the vertical gates VG aligned in the first direction X to a metallic track M1 of a first metal level.

In particular, this allows not breaking the electrical continuity usually existing via the non-individualized gate trench TRG, and thus being able to adapt this manufacturing method to existing and characterized electrical circuits, without the need for a complete (re) design of the circuit.

For example, the transistors thus formed are adapted to implement functions of logic circuits, such as state machines.

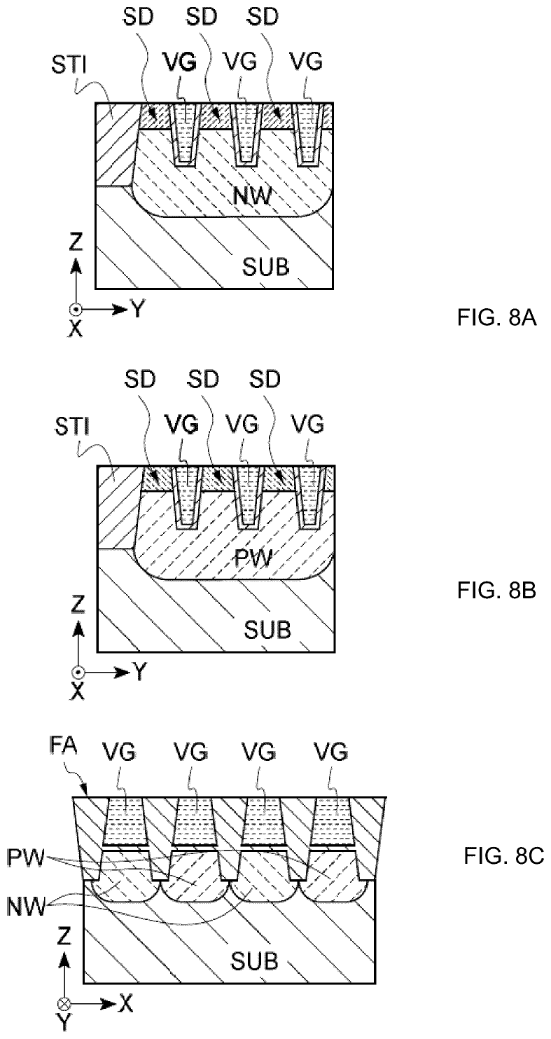

In this respect, reference is made to FIGS. 8A, 8B and 8C illustrating an example of application in a “Complementary Metal Oxide Semiconductor” (CMOS) type logic circuit.

FIG. 8A illustrates a section in a plane XY of the CMOS logic circuit, including P-type “PMOS” logic transistors.

FIG. 8B illustrates a section in a plane XY of the CMOS logic circuit, including N-type “NMOS” logic transistors.

FIG. 8c illustrates a section in a plane XZ of the CMOS logic circuit, including P-type “PMOS” and N-type “NMOS” logic transistors.

For example, the PMOS transistors correspond to the transistors with vertical gates described before in connection with step 700, in the case where an N-type doped well NW has been implanted in the portion corresponding to the active region ACT of these transistors.

For example, the implantation of the well NW could have been done in the semiconductor substrate SUB, prior to the first etchings TR1 of step 300.

The conduction regions SD of the transistors PMOS are strongly P-type doped, typically.

For example, the transistors NMOS correspond to the transistors with vertical gates described before in connection with step 700, in the case where a P-type doped well PW has been implanted in the portion corresponding to the active region ACT of these transistors.

For example, the implantation of the well PW could have been done in the semiconductor substrate SUB, prior to the first etchings TR1 of step 300. In practice, the semiconductor substrate SUB may be originally P-type doped, in which case the implantation of the PW as such is not performed.

Typically, the conduction regions SD of the transistors NMOS are strongly N-type doped.

One could note in the first direction X in the plane XZ, a series of P-type wells PW and N-type wells NW alternately, respectively under each vertical gate.

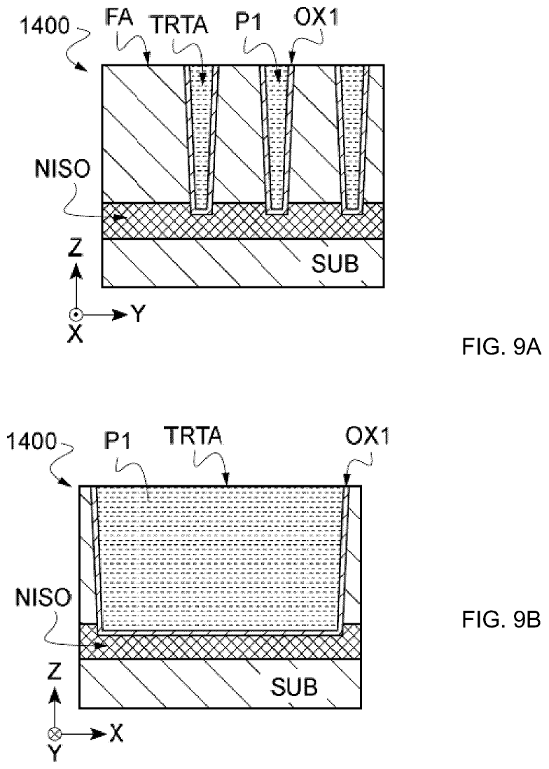

Reference is now made to FIGS. 9A-9B, 10A-10B and 11A-11C, which illustrate steps 1400, 1600, 1700 of forming second vertical gates TRTA and active regions ACT of transistors, in a second case where the vertical gates VG have a second depth larger than the depth of shallow insulation regions STI.

In particular, the second vertical gates are adapted to selection transistors, typically coupled in series with floating-gate state transistors, in memory cells of a non-volatile memory, in particular a memory of the source side injection cell type (commonly referred to as “Source Side Injection” (SSI)).

FIG. 9A illustrates step 1400 in the plane YZ of the same orthogonal reference frame XYZ.

FIG. 9B illustrates step 1400 in the plane XZ of the same orthogonal reference frame XYZ.

Step 1400 substantially corresponds to the implementation of the previously-described steps 300 and 400, wherein gate trenches TRTA have been etched vertically in the substrate SUB, deeper than the first trench TR1 of step 300, up to a source region NISO implanted beforehand in depth in the substrate SUB.

Thus, in particular, the gate trenches TRTA extend lengthwise in the first direction X, include a gate conductive material volume P1 wrapped by a dielectric layer OX1.

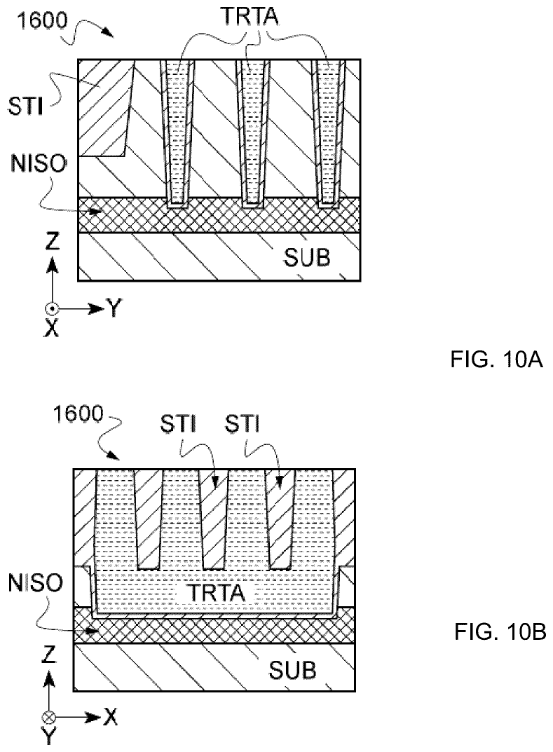

FIG. 10A illustrates step 1600 in the same plane YZ as FIG. 9A.

FIG. 10B illustrates step 1600 in the same plane XZ as FIG. 9B.

Step 1600 corresponds substantially to the implementation of the previously-described steps 500 and 600, wherein shallow insulation trenches STI have been formed, at a depth smaller than that of the gate trenches TRTA. For example, step 1600 may correspond exactly to the implementation of the previously-described steps 500 and 600, in particular with shallow insulation trenches STI having the same depth.

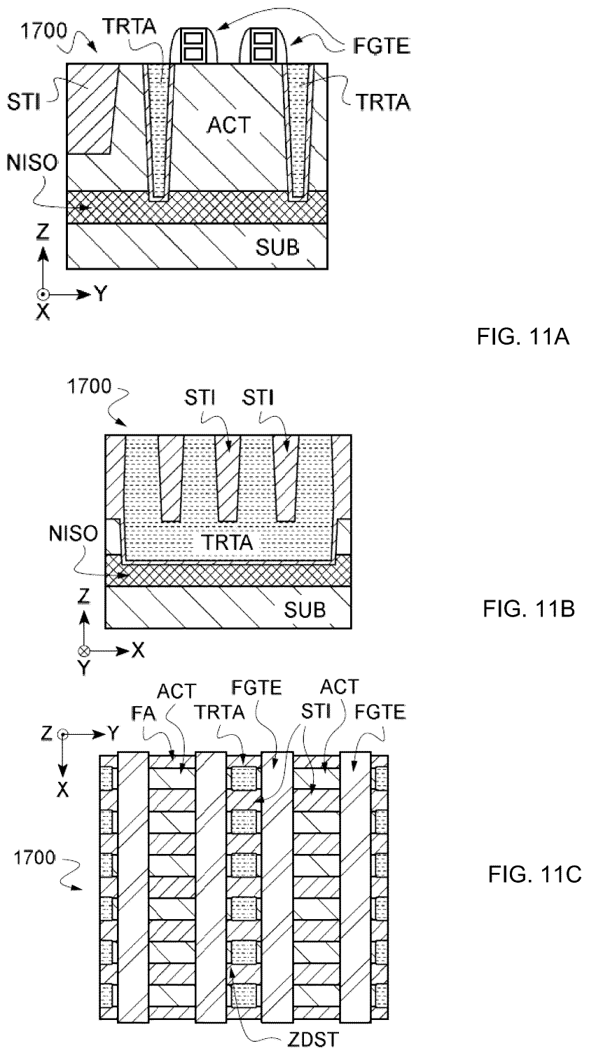

FIG. 11 illustrates step 1700 in the same plane YZ as FIGS. 9A and 10A.

FIG. 11B illustrates step 1700 in the same plane XZ as FIGS. 9B and 10B.

FIG. 11C illustrates step 1700 in a plane XY of a top view of the front face FA.

Step 1700 corresponds to forming a floating-gate state transistor FGTE, forming memory cells with the selection transistors obtained by forming gate trenches TRTA, the buried source region NISO and a conduction region (not shown) common to the selection transistor and to the state transistor FGTE.

Thus, as described before with reference to FIGS. 3A to 3C, 4A to 4C, 5A to 5C, and 6A to 6C, the shallow insulation trenches STI delimit therebetween the active regions ACT, and also delimit therebetween the gate trenches TRG in the first direction X in a self-aligned manner.

However, in this second case, the vertical gate trenches TRTA are not individualized in the first direction X, whereby the shallow insulation trenches STI do not reach the bottom.

Thus, the electrical continuity along the vertical gates TRTA, in the first direction X, is kept compatible with the conventional circuits and characterizations of the non-volatile memories.

In particular, it should be noted that it results from the self-alignment that the width wtX, wbX of the vertical gates VG in the first direction X is strictly equal to the width waX of the active regions ACT in the first direction X, at any identical depth Z between the front face FA and the bottom (BT2) of the shallow insulation trenches STI.

Besides, we also find the structure wherein the width in the first direction X of the gate trenches TRTA is larger in depth than the width in the first direction X of the gate trenches TRTA at the front face FA (FIG. 11B); whereas the width of the gate trenches TRTA in the second direction Y is larger at a front face FA of the substrate than in depth (FIG. 11A).

Finally, the “self-aligned” delimitation of the gate trench TRTA by the shallow insulation trenches STI also allows solving a problem of charge static loss by retention in the floating gate (commonly so-called “disturb”), usually caused by a capacitive coupling between the floating gate and the gate trench TRTA in an area ZDST located outside the alignment of the active regions ACT.

Indeed, given the subsequent formation of the shallow insulation trenches STI, in the area ZDST, the portions of the floating gate that extend over the shallow insulation trenches STI (so-called “flanges”), do not extend opposite the polysilicon portion TRTA. Consequently, the parasitic couplings between the gate trench TRTA and the “flanges” of the floating gate are de facto reduced to a minimum.

1. A method for manufacturing an integrated circuit, comprising:
forming vertical gates of transistors in a semiconductor substrate having a front face by:
forming gate trenches in the front face extending in a first direction; and
subsequently, forming shallow insulation trenches in the front face extending in a second direction perpendicular to the first direction;
wherein the active regions and the vertical gates are delimited between the shallow insulation trenches.

2. The method according to claim 1, wherein forming gate trenches comprises:
etching first trenches sinking vertically into the substrate from the front face and extending longitudinally in the first direction;
wherein sidewalls of the first trenches have an inclination directed so that a width of the first trenches, in the second direction, is larger at the front face than at a bottom of the first trenches.

3. The method according to claim 1, wherein forming shallow insulation trenches comprises:
etching second trenches sinking vertically into the substrate from the front face and extending longitudinally in the second direction;
wherein sidewalls of the second trenches have an inclination directed so that a width of the active regions and the vertical gates delimited therebetween, in the first direction, is larger at a bottom of the first trenches than at the front face.

4. The method according to claim 1, further comprising forming metallic contacts connecting the vertical gates, wherein said metallic contacts are aligned in the first direction and connected to a metallic track in at least one first metal level.

5. The method according to claim 1, wherein forming the gate trenches comprises forming first gate trenches having a first depth smaller than the depth of the shallow insulation regions.

6. The method according to claim 5, wherein forming the gate trenches comprises forming second gate trenches having a second depth larger than the depth of the shallow insulation regions.

7. The method according to claim 1, further comprising, before forming gate trenches, forming a series of P-type wells and of N-type wells in the semiconductor substrate, said P-type and N-type wells alternating in the first direction and positioned opposite locations for the active regions.

8. An integrated circuit, including:
a semiconductor substrate having a front face;
a plurality of transistors in the semiconductor substrate, each transistor including a vertical gate in the semiconductor substrate;
wherein the vertical gates are laterally delimited by:
shallow insulation trenches located on either side of the vertical gates in a first direction of a plane of the front face; and
active regions of the semiconductor substrate located on either side of the vertical gates in a second direction of the plane of the front face, said second direction extending perpendicular to the first direction;
wherein a width of the vertical gates in the first direction is strictly equal to a width of the active regions in the first direction.

9. The integrated circuit according to claim 8, wherein sidewalls of the vertical gates, located on either side of the vertical gates in the first direction, have an inclination directed so that the width of the vertical gates in the first direction is larger at a bottom of the vertical gates than at the front face.

10. The integrated circuit according claim 8, wherein sidewalls of the vertical gates, located on either side of the vertical gates in the second direction, have an inclination directed so that a width of the vertical gates in the second direction is larger at the front face than at a bottom of the vertical gates.

11. The integrated circuit according to claim 8, further comprising:
metallic contacts connecting to the vertical gates;
wherein said metallic contacts are aligned in the first direction and connected to a metallic track in at least one first metal level.

12. The integrated circuit according to claim 8, wherein the transistors with vertical gates include a group of transistors including first vertical gates having a first depth smaller than the depth of the shallow insulation regions.

13. The integrated circuit according to claim 12, wherein the transistors with vertical gates include a group of transistors including second vertical gates having a second depth larger than the depth of the shallow insulation regions.

14. The integrated circuit according to claim 8, wherein the active regions include a series of P-type wells and of N-type wells, said P-type and N-type wells alternating in the first direction.
